(19) United States
(12) Patent Application Publication
(10) Pub. No.: US 2014/0251658 A1
(43) Pub. Date: Sep. 11, 2014

(54) THERMALLY ENHANCED WIRING BOARD WITH BUILT-IN HEAT SINK AND BUILD-UP CIRCUITRY

(71) Applicant: BRIDGE SEMICONDUCTOR CORPORATION, Taipei City (TW)

(72) Inventors: Charles W.C. LIN, Singapore (SG); Chia-Chung WANG, Hsinchu (TW)

(73) Assignee: BRIDGE SEMICONDUCTOR CORPORATION, Taipei City (TW)

(21) Appl. No.: 13/788,144

(22) Filed: Mar. 7, 2013

(51) Int. Cl. H05K 1/02

(52) U.S. Cl. CPC H05K 1/0271
USPC 174/252

(57) ABSTRACT

A thermally enhanced wiring board includes a heat sink, a stiffener and a build-up circuitry. The heat sink extends into an aperture of the stiffener and is thermally connected to the build-up circuitry. The build-up circuitry covers the heat sink and the stiffener and provides signal routing for the stiffener. The stiffener provides signal routing and mechanical support for the build-up circuitry.

### CROSS REFERENCE TO RELATED APPLICATION

This application is a continuation-in-part of U.S. application Ser. No. 13/615,819 filed Sep. 14, 2012, a continuation-in-part of U.S. application Ser. No. 13/733,226 filed Jan. 3, 2013 and a continuation-in-part of U.S. application Ser. No. 13/738,314 filed Jan. 10, 2013, each of which is incorporated by reference.

U.S. application Ser. No. 13/615,819 filed Sep. 14, 2012, U.S. application Ser. No. 13/733,226 filed Jan. 3, 2013 and U.S. application Ser. No. 13/738,314 filed Jan. 10, 2013 all claim the benefit of filing date of U.S. Provisional Application Ser. No. 61/682,801 filed Aug. 14, 2012.

### BACKGROUND OF THE INVENTION

1. Field of the Invention

The present invention relates to a wiring board, and more particularly to a thermally enhanced wiring board with a built-in heat sink, a stiffener and a build-up circuitry for semiconductor assembly.

2. Description of Related Art

Semiconductor devices have high voltage, high frequency and high performance applications that require substantial power to perform the specified functions. As the power increases, the semiconductor device generates more heat. For portable electronics, the heat accumulation can be further aggravated by high packing density and small profile sizes which reduce the surface area to dissipate the heat.

Semiconductor devices are susceptible to performance degradation as well as short life span and immediate failure at high operating temperatures. The heat not only degrades the chip, but also imposes thermal stress on the chip and the surrounding elements due to thermal expansion mismatch. As a result, the chip must be assembled to a thermal board so that the generated heat can be dissipated rapidly and efficiently from the chip to the board and to the ambient environment to ensure effective and reliable operation.

A good and effective design of thermal board typically requires heat conduction and heat spreading to a much larger surface area than the chip or a heat sink it is mounted on. In addition, thermal boards need to provide electrical routing and mechanical support for semiconductor devices. As such, thermal boards usually include a heat spreader or heat sink for heat removal, and an interconnect substrate for signal routing that includes pads for electrical connection to the semiconductor device and terminals for electrical connection to the next level assembly.

Conventional plastic ball grid array (PBGA) packages have a laminated substrate and a chip enclosed in a plastic housing and is attached to a printed circuit board (PCB) by solder balls. The laminated substrate includes a dielectric layer that often includes fiberglass. The heat from the chip flows through the plastic and the dielectric layer to the solder balls and then the PCB. However, since the plastic and the dielectric layer typically have low thermal conductivity, the PBGA provides poor heat dissipation.

Quad-Flat-No Lead (QFN) packages have the chip mounted on a copper die pad which is soldered to the PCB. The heat from the chip flows through the die pad to the PCB. However, since the lead frame type interposer has limited routing capability, the QFN package cannot accommodate high input/output (I/O) chips or passive elements.

U.S. Pat. No. 6,507,102 to Juskey et al. discloses an assembly in which a composite substrate with fiberglass and cured thermosetting resin includes a central opening, a heat sink with a square or rectangular shape resembling the central opening is attached to the substrate at sidewalls of the central opening, top and bottom conductive layers are attached to the top and bottom of the substrate and electrically connected to one another by plated through-holes through the substrate, a chip is mounted on the heat sink and wire bonded to the top conductive layer, an encapsulant is molded on the chip and solder balls are placed on the bottom conductive layer. This structure allows the heat flows from the chip through the heat sink to the ambient environment. However, since the heat sink is barely adhered to the surrounded substrate from the sidewalls, fragile due to inadequate support and prone to crack during thermal cycling make this circuit board prohibitively unreliable for practical usage.

U.S. Pat. No. 6,528,882 to Ding et al. discloses a thermal enhanced ball grid array package in which the substrate includes a metal core layer. The chip is mounted on a die pad region at the top surface of the metal core layer, an insulating layer is formed on the bottom surface of the metal core layer, blind vias extend through the insulating layer to the metal core layer, thermal balls fill the blind vias and solder balls are placed on the substrate and aligned with the thermal balls. The heat from the chip flows through the metal core layer to the thermal balls to the PCB. However, since the metal core layer is conductive and sandwiched between the patterned trace layers, it limits the routing feasibility between the top and bottom patterned trace layers.

U.S. Pat. No. 6,670,219 to Lee et al. discloses a cavity down ball grid array (CDBGA) package in which a ground plate with a central opening is mounted on a heat spreader to form a thermal dissipating substrate. A substrate with a central opening is mounted on the ground plate using an adhesive with a central opening. A chip is mounted on the heat spreader in a cavity defined by the central opening in the ground plate and solder balls are placed on the substrate. However, since the solder balls extend above the substrate, the heat spreader does not contact the PCB. As a result, the heat spreader releases the heat by thermal convection rather than thermal conduction which severely limits the heat dissipation.

U.S. Pat. No. 7,038,311 to Woodall et al. discloses a thermal enhanced BGA package in which a heat sink with an inverted T-like shape is mounted on a window of a substrate to provide efficient heat dissipation from the chip through the pedestal to the expanded base to the PCB. However, much like other drop-in heat sink types, the circuit board is fragile, unbalanced and may warp during assembly. This creates enormous concerns in reliability and low yield.

Conventional thermal boards thus have major deficiencies. For instance, dielectrics with low thermal conductivity such as epoxy limit heat dissipation, whereas inserted heat sink may warp during manufacture or prematurely delaminate or fail during operation due to the heat. The lead frame type substrate may have limited routing capability or multi-layer circuitry with thick dielectric layers would reduce heat dissipation. The heat spreader may be inefficient, cumbersome or difficult to thermally connect to the next level assembly. The manufacturing process may be unsuitable for low cost, high volume manufacture.

### SUMMARY OF THE INVENTION

The present invention has been developed in view of such a situation, and an object thereof is to provide a thermally enhanced wiring board in which a heat sink which has excellent heat storage and dissipation capability is inserted into a stiffener and further spreading by a build-up circuitry. The stiffener can provide mechanical support and signal routing for the build-up circuitry. The build-up circuitry is thermally connected to the heat sink and electrically connected to the stiffener. In summary, the thermal conduction pathway of the wiring board is provided by the heat sink and the conductive via formed in the build-up circuitry that contacts heat sink directly. The electrical connection of the wiring board is retained by plated through hole in the stiffener and conductive via in the build-up circuitry for flexible signal routing. Accordingly, the present invention provides an effective and robust thermally enhanced wiring board that includes a heat sink, a stiffener and a build-up circuitry.

In a preferred embodiment, the heat sink extends into an aperture of the stiffener, and includes a first surface that faces the first vertical direction and a parallel second surface that faces the second vertical direction. The heat sink can be a solid metal slug or an electrical insulator such as ceramic plate coated with metallic film. For instance, heat sink can be a copper or aluminum slug, or aluminum oxide (Al₂O₃), aluminum nitride (AlN), or silicon nitride (SiN) plate coated with copper, or other inorganic materials such as silicon or glass plate coated with copper.

The stiffener can include a first patterned wiring layer, a second patterned wiring layer and an aperture. The first patterned wiring layer that faces the first vertical direction can be electrically connected to the second patterned wiring layer that faces the second vertical direction through one or more plated through holes. The aperture of the stiffener can be in close proximity to and be laterally aligned with peripheral edges of the heat sink in the lateral direction to prevent the heat sink from undesirable movement. For instance, a gap in between the heat sink and the aperture of the stiffener can be in a range of about 0.001 to 1 mm. The stiffener can extend to peripheral edges of the wiring board and provide mechanical support to suppress warp and bend of the wiring board. Moreover, the stiffener also provides signal routing for the build-up circuitry. The stiffener can be a single or multi-layer structure such as multi-layer circuit board or a dielectric laminate with through via and conductive layer formed thereon. The stiffener can be made of organic materials such as epoxy, polyimide or copper-clad laminate. The stiffener can also be made of ceramics or other various inorganic materials, such as aluminum oxide (Al₂O₃), aluminum nitride (AlN), silicon nitride (SiN), silicon (Si), glass, etc.

The build-up circuitry covers the heat sink and the stiffener and provides thermal conduction for the heat sink and electrical routing for the stiffener. The build-up circuitry can include a first dielectric layer and one or more first conductive traces. For instance, the first dielectric layer covers the heat sink and the stiffener in the first vertical direction and can extend to peripheral edges of the wiring board, and the first conductive traces extend from the first dielectric layer in the first vertical direction. Moreover, the first dielectric layer can extend into a gap between the stiffener and the heat sink.

The first dielectric layer includes one or more first via openings that are disposed adjacent to the heat sink and adjacent to the first patterned wiring layer of the stiffener. One or more first conductive traces are disposed on the first dielectric layer (i.e. extend from the first dielectric layer in the first vertical direction and extend laterally on the first dielectric layer) and extend into the first via openings in the second vertical direction to provide thermal connection for the heat sink and provide electrical signal routing for the first patterned wiring layer of the stiffener. Specifically, the first conductive traces can directly contact the heat sink, and thus the thermal conduction pathway can be established without using other materials such as conductive adhesive or solder. The first conductive traces can also contact the first patterned wiring layer of the stiffener to provide signal routing for the stiffener, and thus the electrical connection between the stiffener and the build-up circuitry can be devoid of solder. In addition, the first conductive traces can provide an electrical interconnection between the first patterned wiring layer of the stiffener and the heat sink disposed at the aperture of the stiffener for ground/power connection purpose. The build-up circuitry can include additional layers of dielectric, additional layers of via openings, and additional layers of conductive traces if needed for further signal routing and heat dissipation.

The build-up circuitry can include one or more terminal pads to provide thermal and electrical contacts for the next level assembly. The terminal pads extend to or beyond the first conductive traces in the first vertical direction and include an exposed contact surface that faces in the first vertical direction. For instance, the terminal pad can be adjacent to and integral with the first conductive trace.

The thermally enhanced wiring board of the present invention can further include an adhesive. The heat sink and the stiffener can be affixed and mechanically connected to the build-up circuitry using the adhesive. Thus, the adhesive can contact the heat sink and the stiffener and is sandwiched between the heat sink and the build-up circuitry and between the stiffener and the build-up circuitry. Alternatively, the stiffener can be mechanically connected to the build-up circuitry using an interlayer dielectric that contacts and is sandwiched between the stiffener and the build-up circuitry and can further extend into a gap between the heat sink and the stiffener.

The thermally enhanced wiring board of the present invention can further include a stopper. The stopper that serves as a placement guide for the heat sink can be in close proximity to and laterally aligned with and laterally extend beyond the outer peripheral edges of the heat sink in lateral directions. The stopper for the heat sink can be made of a metal, a photosensitive plastic material or non-photosensitive material, such as copper, aluminum, nickel, iron, tin, alloys, epoxy or polyimide.

The stopper can contact and extend from the first dielectric layer in the second vertical direction and has patterns against undesirable movement of the heat sink. For instance, the stopper can include a continuous or discontinuous strip or an array of posts. Specifically, the stopper can be laterally aligned with four lateral surfaces of the heat sink to stop the lateral displacement of the heat sink. For instance, the stopper can be aligned along and conform to four sides, two diagonal corners or four corners of the heat sink and a gap in between the heat sink and the stopper preferably is in a range of about 0.001 to 1 mm. The heat sink can be spaced from the inner wall of the aperture by the stopper, and a bonding material can be added between the heat sink and the stiffener to enhance rigidity. Moreover, the stopper can also be in close proximity to and laterally aligned with the inner wall of the aperture to stop the lateral displacement of the stiffener. The stopper preferably has a thickness in a range of 10-200 microns.

The present invention can provide a thermally enhanced semiconductor assembly in which a semiconductor device such as chip can be attached to the heat sink directly and electrically connected to the second patterned wiring layer of the stiffener using a wide variety of connection media including gold wire. In addition, the semiconductor device can be attached to the build-up circuitry using solder bumps and thermally connected to the heat sink and electrically connected to the first patterned wiring layer of the stiffener through the build-up circuitry.

The thermally enhanced wiring board of the present invention can further include a second build-up circuitry so that the heat sink and the stiffener is sandwiched between the first build-up circuitry and the second build-up circuitry. The second build-up circuitry covers the heat sink and the stiffener in the second vertical direction and provides thermal conduction for the heat sink and electrical routing for the stiffener. The second build-up circuitry can include a second dielectric layer and one or more second conductive traces. For instance, the second dielectric layer covers the heat sink and the stiffener in the second vertical direction and can extend to peripheral edges of the wiring board, and the second conductive traces extend from the second dielectric layer in the second vertical direction.

The second dielectric layer includes one or more second via openings that are disposed adjacent to the heat sink and adjacent to the second patterned wiring layer of the stiffener. One or more second conductive traces are disposed on the second dielectric layer (i.e. extend from the second dielectric layer in the second vertical direction and extend laterally on the second dielectric layer) and extend into the second via openings in the first vertical direction to provide thermal connection for the heat sink and provide electrical signal routing for the second patterned wiring layer of the stiffener. Specifically, the second conductive traces can directly contact the heat sink, and thus the thermal conduction pathway can be established without using other materials such as conductive adhesive or solder. The second conductive traces can also contact the second patterned wiring layer of the stiffener to provide signal routing for the stiffener, and thus the electrical connection between the stiffener and the second build-up circuitry can be devoid of solder. In addition, the second conductive traces can also provide an electrical interconnection between the second patterned wiring layer of the stiffener and the heat sink disposed at the aperture of the stiffener for ground/power connection purpose. The second build-up circuitry can also include additional layers of dielectric, additional layers of via openings, and additional layers of conductive traces if needed for further signal routing and heat dissipation. In summary, the second build-up circuitry provides an even higher routing capability for the thermally enhanced wiring board and is particularly suitable for high I/O semiconductor devices in dissipating the generated heat.

The present invention has numerous advantages. The through via in the stiffener can provide flexible signal routing when interconnected with build-up circuitry. The strong rigidity of the stiffener can provide a robust mechanical support for the heat sink and the build-up circuitry. The placement location of the heat sink can be accurately confined by the aperture of the stiffener or the stopper to avoid the thermal connection failure between the heat sink and the build-up circuitry resulted from the lateral displacement of the heat sink, thereby improving the manufacturing yield greatly. The direct thermal connection between the heat sink and the build-up circuitry is advantageous for a high thermal conduction pathway. In addition, the direct electrical connection between the stiffener and the build-up circuitry is advantageous for high I/O and high performance applications due to its high routing capability. The thermally enhanced wiring board and the semiconductor assembly using the same are reliable, inexpensive and well-suited for high volume manufacture.

These and other features and advantages of the present invention will be further described and more readily apparent from a review of the detailed description of the preferred embodiments which follows.

### BRIEF DESCRIPTION OF THE DRAWINGS

The following detailed description of the preferred embodiments of the present invention can best be understood when read in conjunction with the following drawings, in which:

FIGS. 1A-1F are cross-section views showing a method of making a thermally enhanced wiring board that includes a stiffener, a heat sink, and a build-up circuitry electrically connected to the stiffener in accordance with an embodiment of the present invention;

FIG. 1G is a cross-sectional view showing a thermally enhanced assembly that includes a semiconductor device attached to heat sink in accordance with an embodiment of the present invention;

FIGS. 2A and 2B are cross-sectional views showing a method of forming stopper on a dielectric layer in accordance with another embodiment of the present invention;

FIG. 2C is a top view corresponding to FIG. 2B;

FIGS. 2A′ and 2B′ are cross-sectional views showing an alternative method of forming a stopper on a dielectric layer;

FIG. 2C′ is a top view corresponding to FIG. 2B′;

FIGS. 2D-2G are top views of other various stopper patterns for reference;

FIGS. 3A-3H are cross-sectional views showing a method of making another wiring board that includes a heat sink, a stopper, a stiffener and build-up circuitry in accordance with another embodiment of the present invention;

FIG. 3I is a cross-sectional view showing a thermally enhanced assembly that includes a semiconductor device attached to a build-up circuitry in accordance with another embodiment of the present invention; and

FIGS. 4A-4D are cross-sectional views showing a method of making yet another wiring board that includes an heat sink, a stopper, a stiffener and dual build-up circuitries in accordance with yet another embodiment of the present invention.

### DETAILED DESCRIPTION OF THE PREFERRED EMBODIMENT

### Embodiment 1

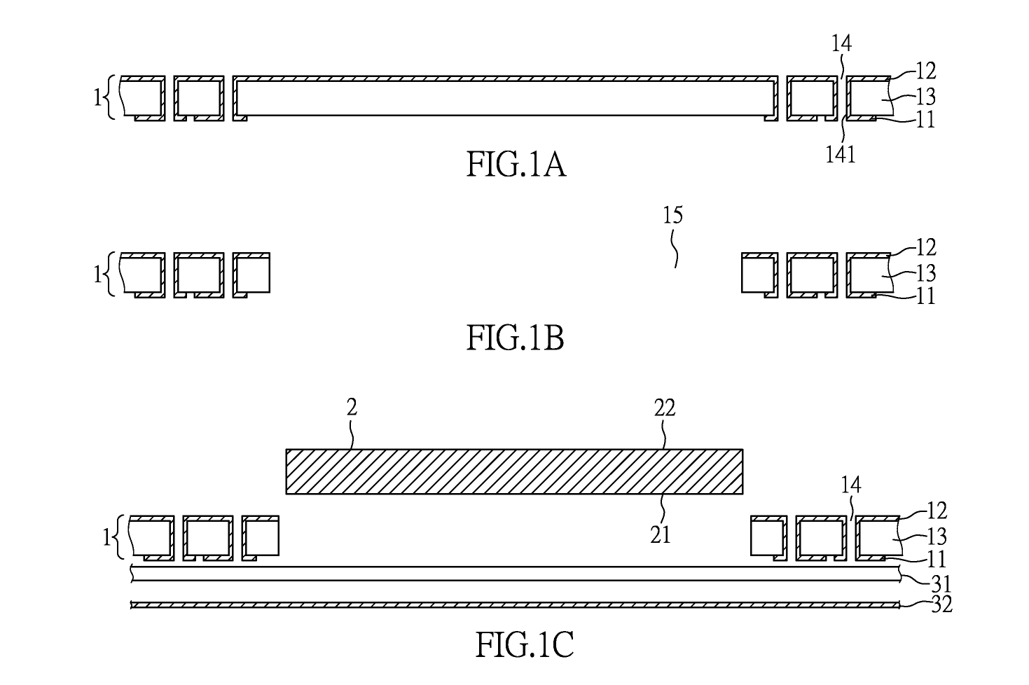

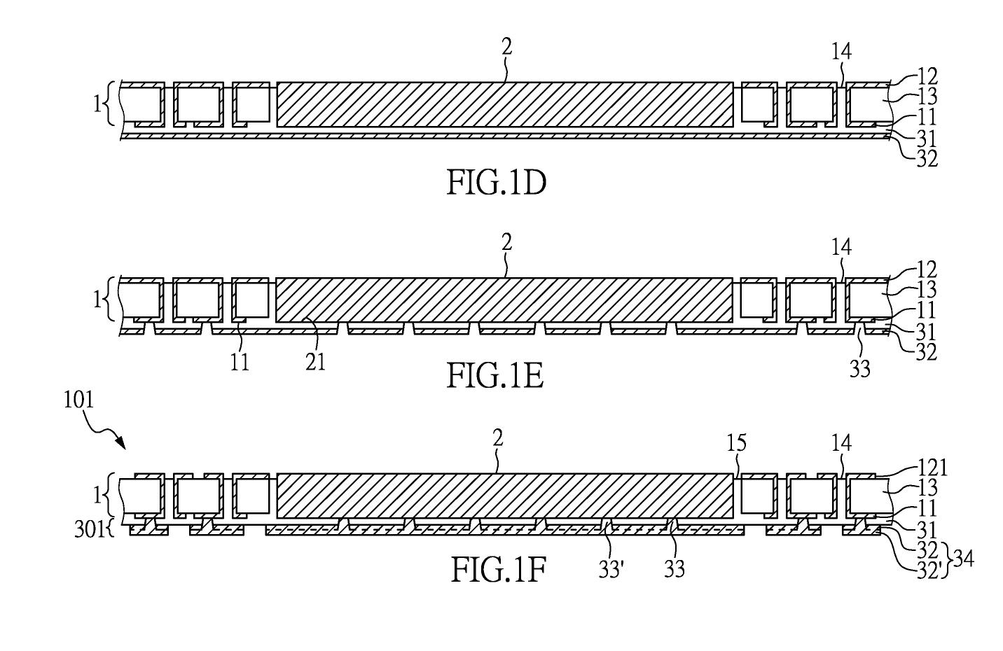

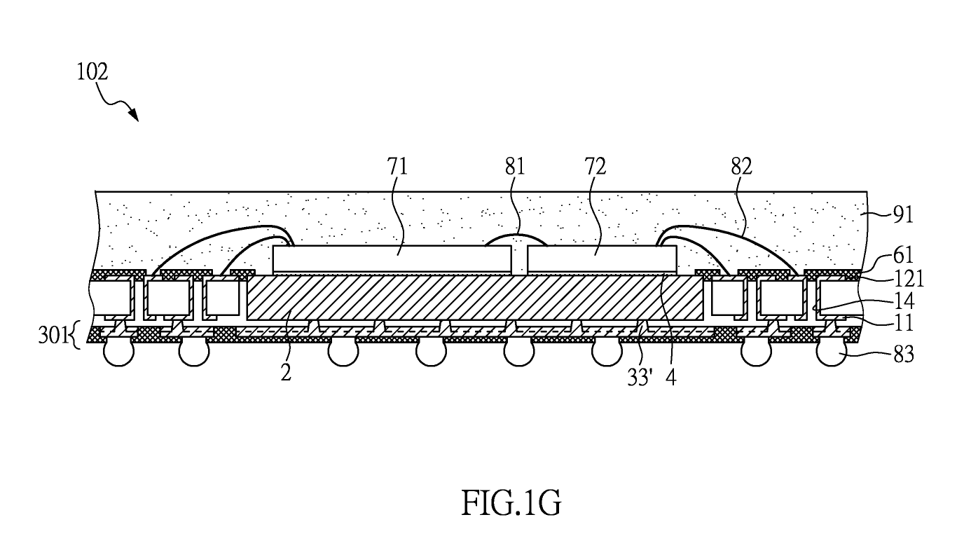

FIGS. 1A-1F are cross-section views showing a method of making a thermally enhanced wiring board that includes a stiffener, a heat sink, and a build-up circuitry electrically connected to the stiffener in accordance with an embodiment of the present invention.

As shown in FIG. 1F, thermally enhanced wiring board 101 includes stiffener 1, heat sink 2, and build-up circuitry 301. Stiffener 1 includes first patterned wiring layer 11, plated through holes 14, second patterned wiring layer 121 opposite to and electrically connected to first patterned wiring layer 11, and aperture 15 where heat sink 2 is inserted into. Build-up circuitry 301 includes first dielectric layer 31, first via openings 33, and first conductive trace 34. Build-up circuitry 301 is thermally connected to the heat sink 2 and is electrically connected to the first patterned wiring layer 11 of stiffener 1 respectively.

FIG. 1A is a cross-sectional view of stiffener 1. Stiffener 1 is illustrated as a laminate that includes first patterned wiring layer 11, insulating layer 13, metal layer 12 and plated through holes 14. First patterned wiring layer 11 extends from insulating layer 13 in the downward direction and is illustrated as a patterned copper layer. Metal layer 12 extends from insulating layer 13 in the upward direction and is illustrated as an un-patterned copper layer. Plated through holes 14 extend vertically through insulating layer 13 and are illustrated as through holes with a connecting layer 141 on inner wall thereof to provide an electrically connection between first patterned wiring layer 11 and metal layer 12.

FIG. 1B is a cross-sectional view of stiffener 1 provided with aperture 15. Aperture 15 is a window that extends through stiffener 1 and has a dimension of 10.1 mm by 10.1 mm. Aperture 15 is formed by mechanical drilling through stiffener 1 and can be formed with other techniques such as punching and laser cutting.

FIGS. 1C and 1D are cross-sectional views showing a method of laminating stiffener 1, heat sink 2, first dielectric layer 31 and metal layer 32. Heat sink 2 is illustrated as a solid metal slug with a dimension of 10 mm by 10 mm and includes first surface 21 facing the downward direction and parallel second surface 22 facing the upward direction. First dielectric layer 31, such as epoxy resin, glass-epoxy, polyimide and the like, is provided between stiffener 1 and metal layer 32 and between heat sink 2 and metal layer 32 and has a thickness of 50 microns. Metal layer 32 is illustrated as a copper layer with a thickness of 15 microns.

Under pressure and heat, heat sink 2 is inserted into aperture 15 of stiffener 1, and first dielectric layer 31 is forced into a gap between stiffener 1 and heat sink 2 and the remaining space in plated through holes 14 by applying upward pressure to metal layer 32 and/or downward pressure to stiffener 1 and heat sink 2. After first dielectric layer 31 and metal layer 32 are laminated with stiffener 1 and heat sink 2, first dielectric layer 31 is solidified. Accordingly, as shown in FIG. 1D, first dielectric layer 31 as solidified provides secure robust mechanical bonds between stiffener 1 and heat sink 2, between metal layer 34 and stiffener 1 and between metal layer 34 and heat sink 2. In this illustration, as heat sink 2 has a dimension of about the same to that of aperture 15, aperture 15 of stiffener 1 is in close proximity to and is laterally aligned with peripheral edges of heat sink 2 in the lateral direction and can prevent the heat sink 2 from undesirable movement and ensure predetermined portions of heat sink 2 being aligned with laser. However, since heat sink 2 has a large thermal connection surface, the lateral movement of heat sink 2 would not result in the thermal connection failure between build-up circuitry 301 and heat sink 2. Thereby, it is not indispensable to prevent lateral displacement of heat sink 2 for this case.

FIG. 1E is a cross-sectional view of the structure showing first via openings 33 formed through metal layer 32 and first dielectric layer 31 to expose and be aligned with first surface 21 of heat sink 2 and first patterned wiring layer 11 of stiffener 1. First via openings 33 may be formed by numerous techniques including laser drilling, plasma etching and photolithography. Laser drilling can be enhanced by a pulsed laser. Alternatively, a scanning laser beam with a metal mask can be used. For instance, copper can be etched first to create a metal window followed by laser. First via openings 33 typically have a diameter of 50 microns.

Referring now to FIG. 1F, first conductive traces 34 are formed on first dielectric layer 31 by depositing plated layer 32′ on metal layer 32 and into first via openings 33 and then patterning metal layer 32 and plated layer 32′ thereon. Alternatively, when laminating blanket dielectric only, first dielectric layer 31 can be directly metallized to form first conductive traces 34 after forming first via openings 33. Also shown in FIG. 1F is second patterned wiring layer 121 formed on insulating layer 13 by patterning metal layer 12.

Plated layer 32′ can be deposited by numerous techniques including electroplating, electroless plating, evaporating, sputtering, and their combinations as a single layer or multiple layers. For instance, plated layer 32′ is deposited by first dipping the structure in an activator solution to render first dielectric layer 31 catalytic to electroless copper, then a thin copper layer is electrolessly plated to serve as the seeding layer before a second copper layer is electroplated on the seeding layer to a desirable thickness. Alternatively, the seeding layer can be formed by sputtering a thin film such as titanium/copper before depositing the electroplated copper layer on the seeding layer. Once the desired thickness is achieved, metal layer 32 and plated layer 32′ can be patterned to form first conductive traces 34 by numerous techniques including wet etching, electro-chemical etching, laser-assist etching, and their combinations with an etch mask (not shown) thereon that defines first conductive traces 34. Accordingly, first conductive traces 34 extend from first dielectric layer 31 in the downward direction, extend laterally on first dielectric layer 31 and extend into first via openings 33 in the upward direction to form first conductive vias 33′, thereby providing thermal connection for heat sink 2 and electrical signal routing for first patterned wiring layer 11 of stiffener 1 respectively.

Metal layer 32 and plated layer 32′ thereon are shown as a single layer for convenience of illustration. The boundary (shown in phantom) between the metal layers may be difficult or impossible to detect since copper is plated on copper. However, the boundary between plated layer 32′ and first dielectric layer 31 is clear.

Accordingly, as shown in FIG. 1F, wiring board 101 is accomplished and includes stiffener 1, heat sink 2, and build-up circuitry 301. In this illustration, build-up circuitry 301 includes first dielectric layer 31 and first conductive traces 34, and covers heat sink 2 and stiffener 1 to provide thermal conduction for heat sink 2 and electrical routing for stiffener 1. Stiffener 1 and heat sink 2 are mechanically connected to first dielectric layer 31 and are spaced from each other by first dielectric layer 31. First conductive traces 34 of build-up circuitry 301 directly contact heat sink 2 and first patterned wiring layer 11 of stiffener 1, and thus the electrical connection between stiffener 1 and build-up circuitry 301 is devoid of solder and the thermal conduction pathway between heat sink 2 and build-up circuitry 301 can be established without using other materials such as conductive adhesive or solder. Plated through holes 14 in stiffener 1 can provide flexible signal routing when interconnected with build-up circuitry 301.

FIG. 1G is a cross-sectional view of a thermally enhanced assembly 102 in which semiconductor devices 71, 72 are electrically connected to each other via wire bonds 81 and are attached to heat sink 2 through adhesive 4 and are electrically connected to second patterned wiring layer 121 via wire bonds 82. In this illustration, solder mask material 61 is disposed over build-up circuitry 301 and second patterned wiring layer 121, and includes solder mask openings where can accommodate a conductive joint, such as solder balls 83, for electrical communication and mechanical attachment with another assembly or external components. Solder mask openings may be formed by numerous techniques including photolithography, laser drilling and plasma etching. Semiconductor devices 71, 72 on heat sink 2 can be electrically connected to build-up circuitry 301 through wire bonds 82, second patterned wiring layer 121, plated through holes 14 and first patterned wiring layer 11. The thermal conduction pathway of the semiconductor assembly 102 is provided by heat sink 2 and first conductive vias 33′ formed in build-up circuitry 301 that contact heat sink 2 directly. Additionally, encapsulant 91 such as molding compound can be applied to protect semiconductor devices 71, 72 and wire bonds 81, 82.

### Embodiment 2

For purposes of brevity, any description in Embodiment 1 is incorporated herein insofar as the same is applicable, and the same description need not be repeated.

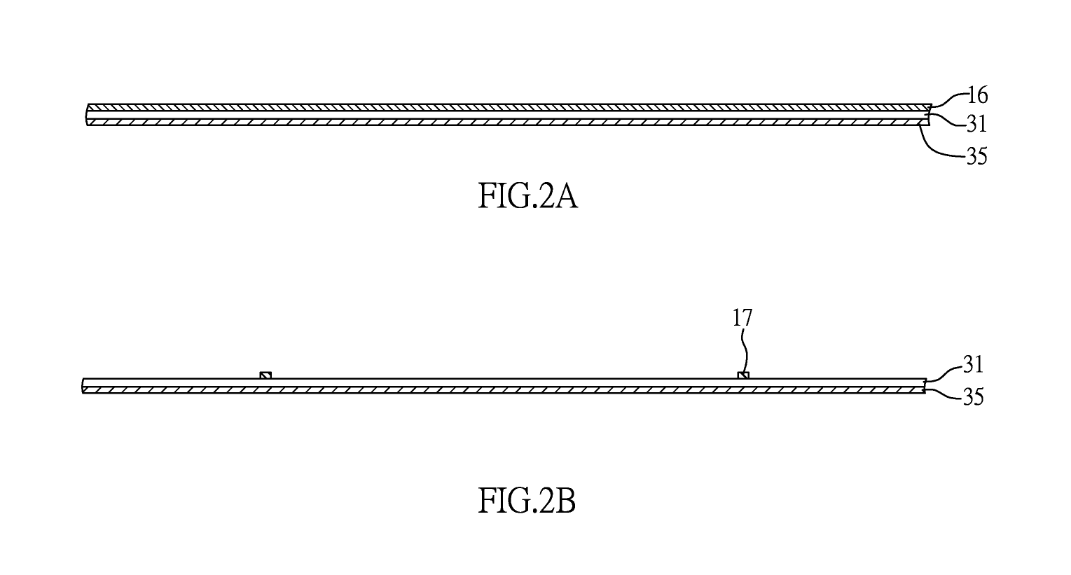

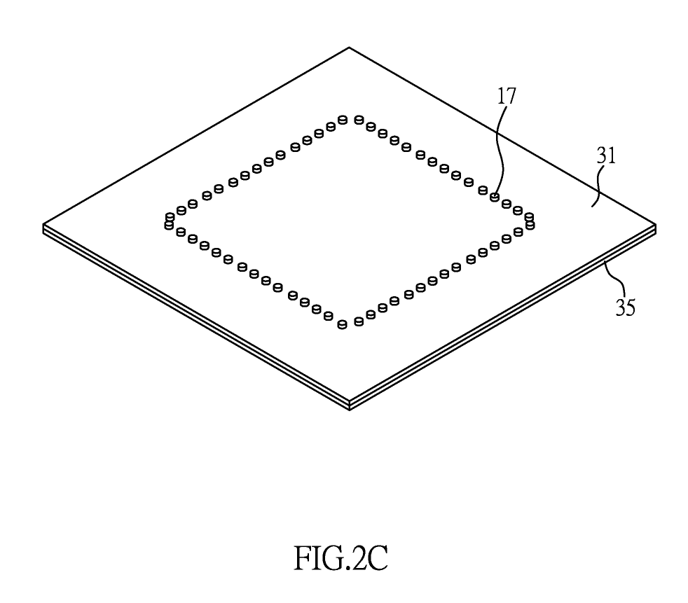

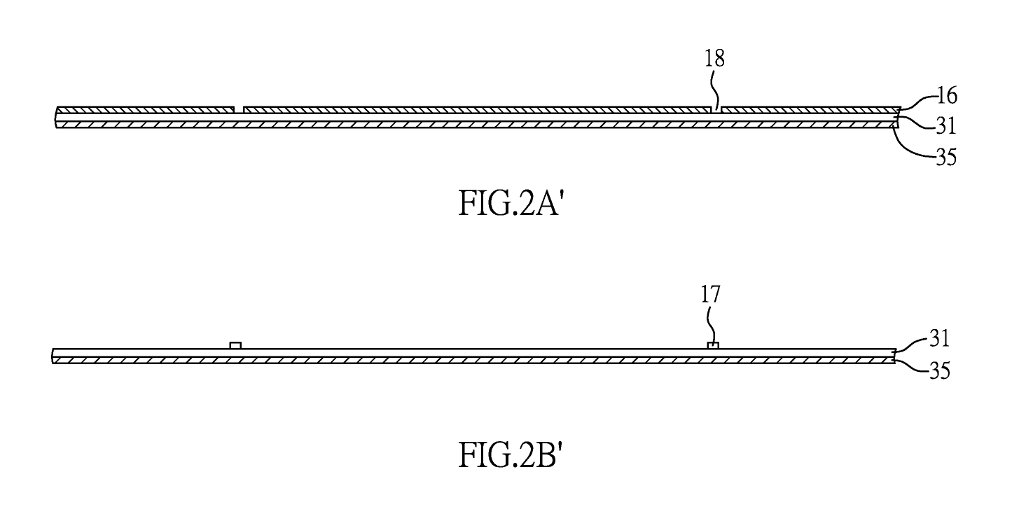

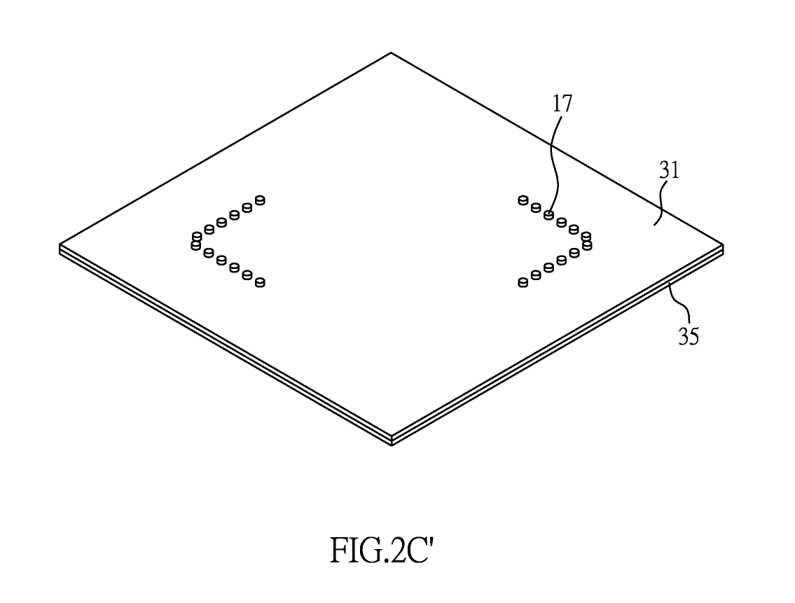

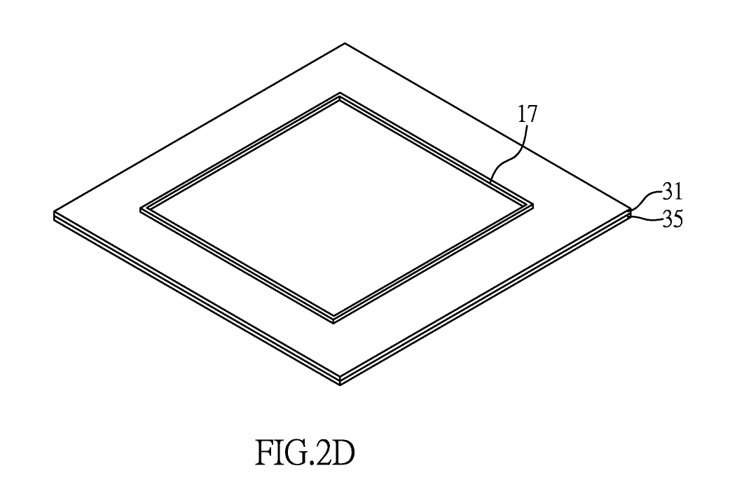

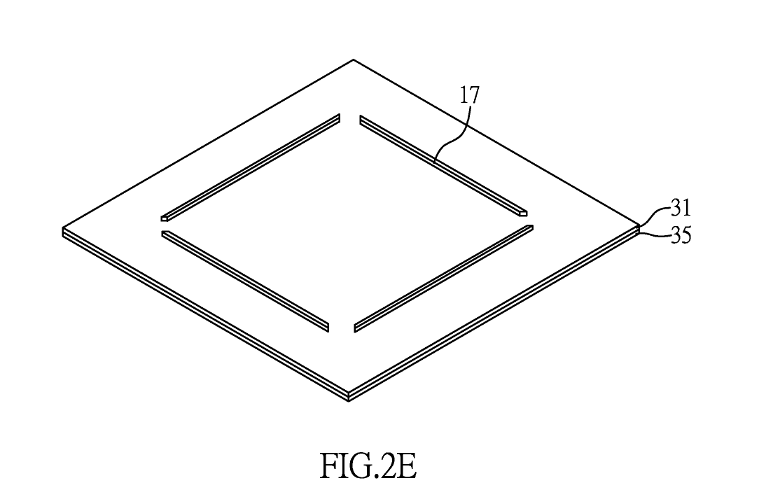

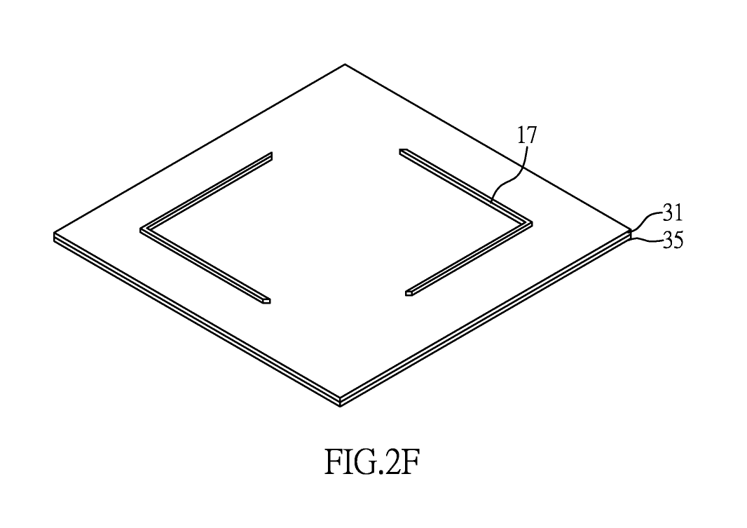

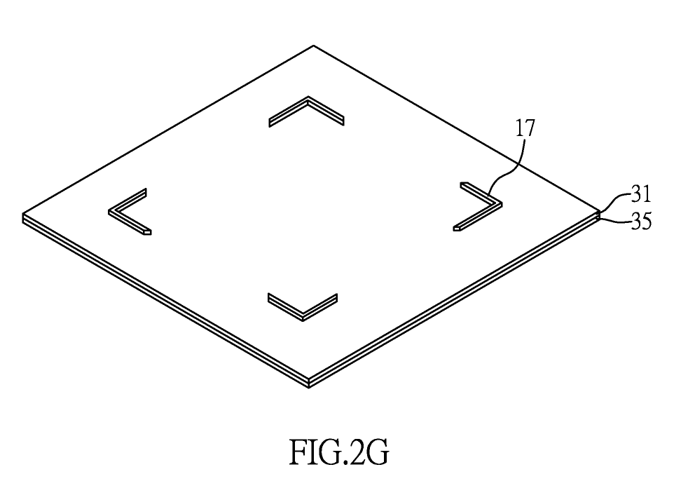

FIGS. 2A and 2B are cross-sectional views showing a method of forming stopper 17 on first dielectric layer 31 in accordance with another embodiment of the present invention, and FIG. 2C is a top view corresponding to FIG. 2B.

FIG. 2A is a cross-sectional view of a laminate substrate that includes metal layer 16, first dielectric layer 31 and support plate 35. Metal layer 16 is illustrated as a copper layer with a thickness of 35 microns. However, metal layer 16 can also be made of other various metal materials and is not limited to a copper layer. Besides, metal layer 16 can be deposited on first dielectric layer 31 by numerous techniques including lamination, electroplating, electroless plating, evaporating, sputtering, and their combinations as a single layer or multiple layers, and preferably has a thickness in a range of 10 to 200 microns.

First dielectric layer 31 typically is made of epoxy resin, glass-epoxy, polyimide and the like and has a thickness of 50 microns. In this embodiment, first dielectric layer 31 is sandwiched between metal layer 16 and support plate 35. However, support plate 35 may be omitted in some embodiments. Support plate 35 typically is made of copper, but copper alloys or other materials are also doable. The thickness of support plate 35 can range from 25 to 1000 microns, and preferably ranges from 35 to 100 microns in consideration of process and cost. In this embodiment, support plate 35 is illustrated as a copper plate with a thickness of 35 microns.

FIGS. 2B and 2C are cross-sectional and top views, respectively, of the structure with stopper 17 formed on first dielectric layer 31. Stopper 17 can be formed by removing selected portions of metal layer 16 using photolithography and wet etching. In this illustration, stopper 17 consists of plural metal posts in a rectangular frame array and conforms to four sides of a heat sink subsequently disposed on first dielectric layer 31. However, stopper patterns are not limited thereto and can be other various patterns against undesirable movement of the subsequently disposed heat sink.

FIGS. 2A′ and 2B′ are cross-sectional views showing an alternative method of forming a stopper on a dielectric layer, and FIG. 2C′ is a top view corresponding to FIG. 2B′.

FIG. 2A′ is a cross-sectional view of a laminate substrate with a set of cavities 18. The laminate substrate includes metal layer 16, first dielectric layer 31 and support plate 35 as above mentioned, and cavities 18 are formed by removing selected portions of metal layer 16.

FIGS. 2B′ and 2C′ are cross-sectional and top views, respectively, of the structure with stopper 17 formed on first dielectric layer 31. Stopper 17 can be formed by dispensing or printing a photosensitive plastic material (e.g., epoxy, polyimide, etc.) or non-photosensitive material into cavities 18, followed by removing overall metal layer 16. Herein, stopper 17 is illustrated as an array of plural resin posts and conforms to two diagonal corners of a subsequently disposed heat sink.

FIGS. 2D-2G are top views of other various stopper patterns for reference. For instance, stopper 17 may consist of a continuous or discontinuous strip and conform to four sides (as shown FIGS. 2D and 2E), two diagonal corners or four corners (as shown in FIGS. 2F and 2G) of a subsequently disposed heat sink.

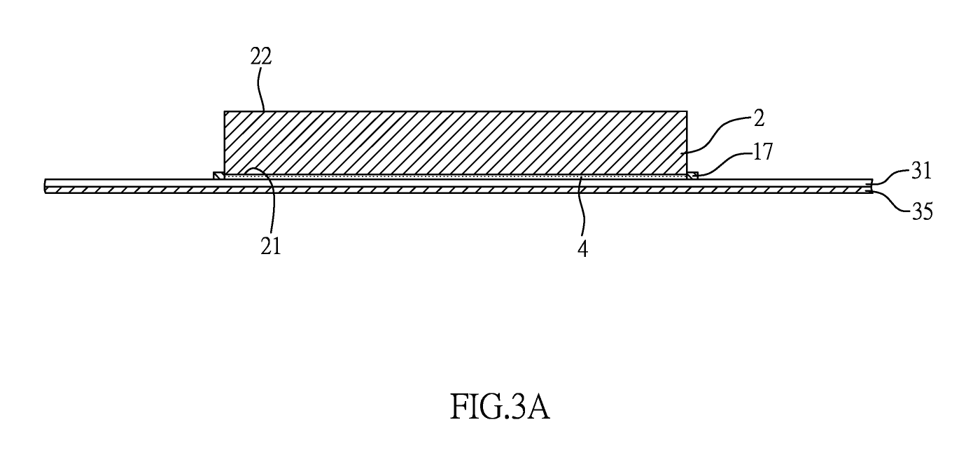

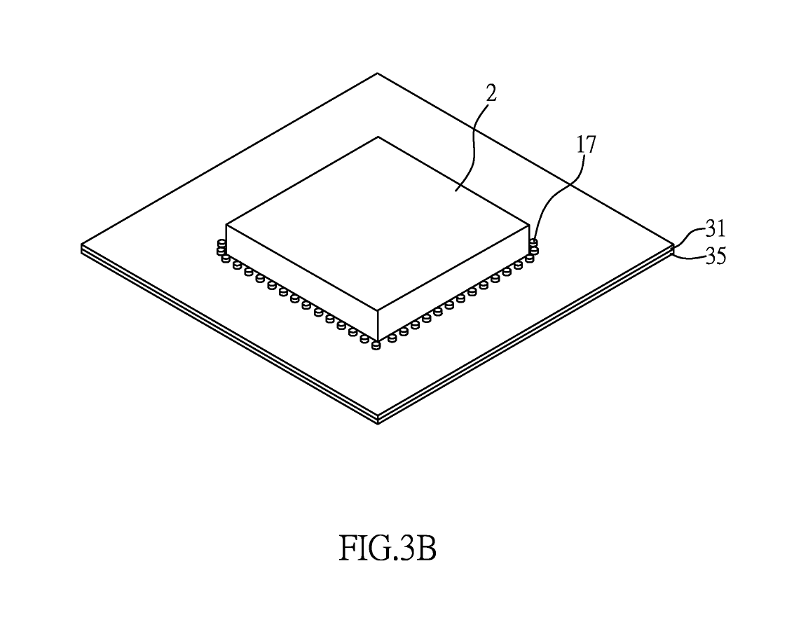

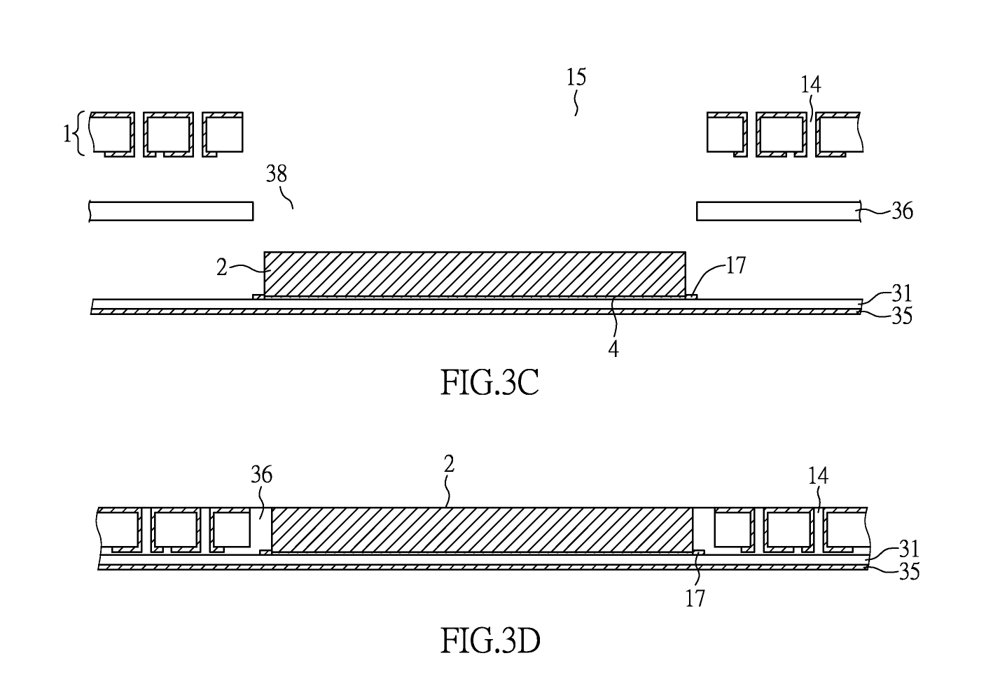

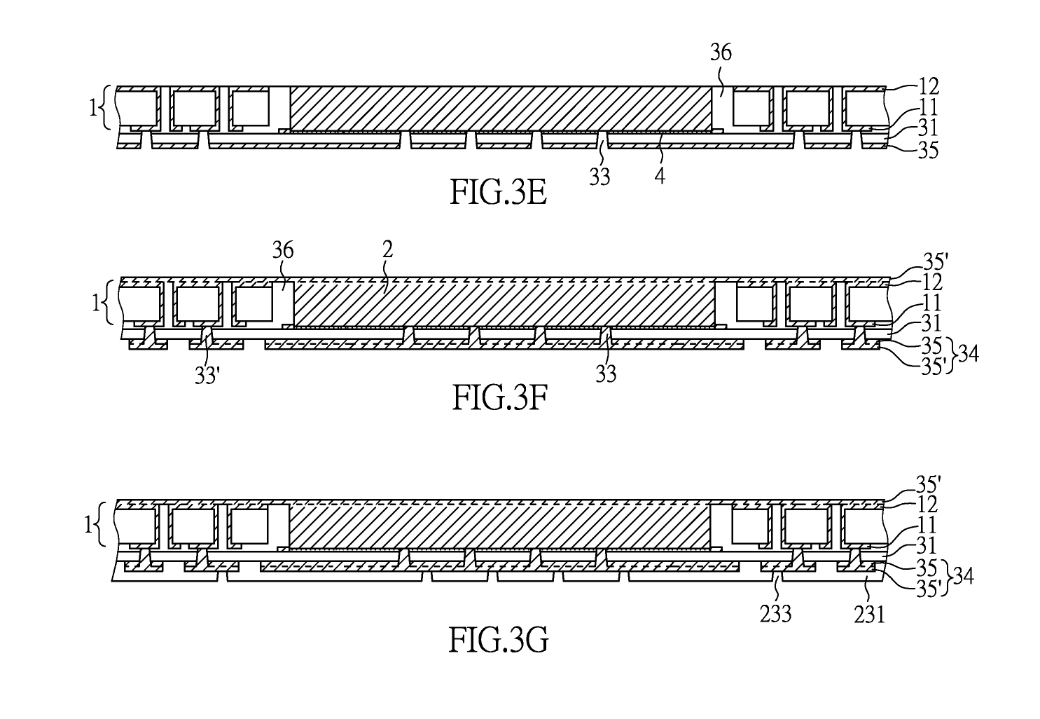

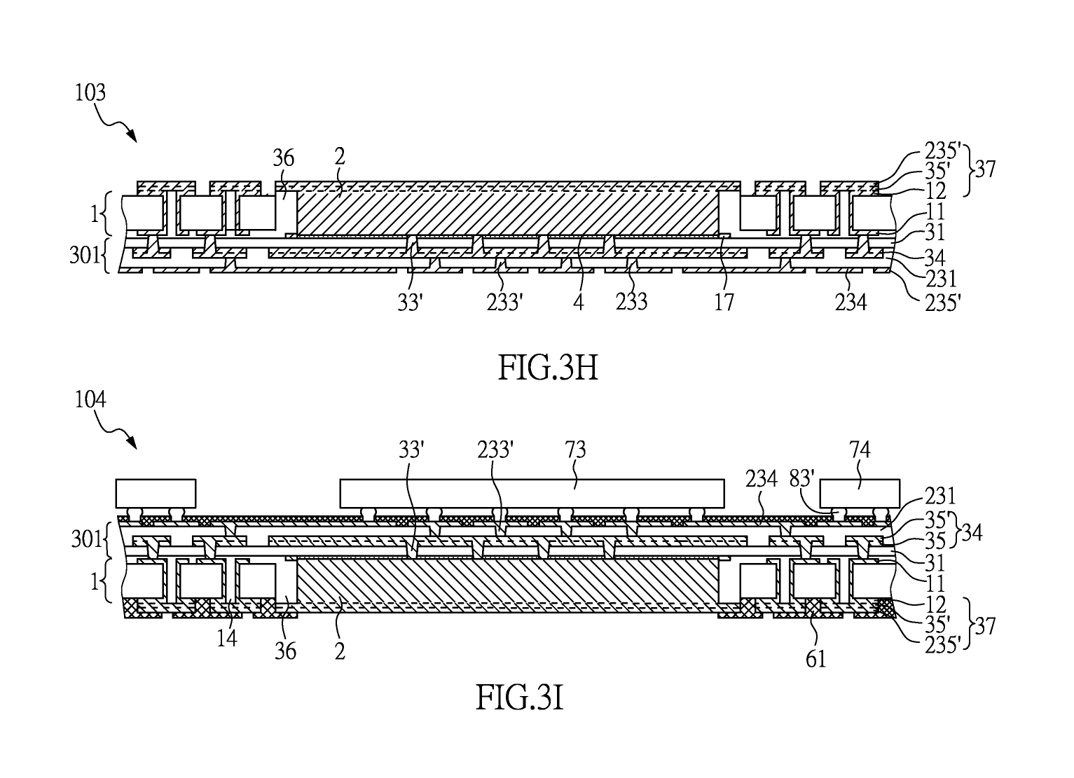

FIGS. 3A-3H are cross-sectional views showing a method of making another wiring board that includes a heat sink, a stopper, a stiffener and build-up circuitry in accordance with another embodiment of the present invention.

FIGS. 3A and 3B are cross-sectional and top views, respectively, of the structure with heat sink 2 mounted on first dielectric layer 31 using adhesive 4. Heat sink 2 includes first surface 21 and second surface 22 opposite to first surface 21 as described above.

Stopper 17 can serve as a placement guide for heat sink 2, and thus heat sink 2 is precisely placed at a predetermined location with its first surface 21 facing first dielectric layer 31. Stopper 17 extends from first dielectric layer 31 beyond first surface 21 of heat sink 2 in the upward direction and is laterally aligned with and laterally extends beyond four sides of heat sink 2 in the lateral directions. As stopper 17 is in close proximity to and conforms to four lateral surfaces of heat sink 2 in lateral directions and adhesive 4 under heat sink 2 is lower than stopper 17, any undesirable movement of heat sink 2 due to adhesive curing can be avoided. Preferably, a gap in between heat sink 2 and stopper 17 is in a range of about 0.001 to 1 mm.

FIGS. 3C-3D are cross-sectional showing a method of laminating stiffener 1 onto first dielectric layer 31 using interlayer dielectric 36. Heat sink 2 is aligned with and inserted into aperture 15 of stiffener 1 and opening 38 of interlayer dielectric 36 sandwiched between stiffener 1 and first dielectric layer 31. Under pressure and heat, interlayer dielectric 36 is forced into plated through holes 14 and a gap between stiffener 1 and heat sink 2 by applying upward pressure to support plate 35 and/or downward pressure to stiffener 1. Accordingly, interlayer dielectric 36 as solidified provides secure robust mechanical bonds between stiffener 1 and heat sink 2 and between stiffener 1 and first dielectric layer 31.

FIG. 3E is a cross-sectional view of the structure showing first via openings 33 formed through support plate 35, first dielectric layer 31 and adhesive 4/interlayer dielectric 36. First via openings 33 are aligned with and expose selected portions of heat sink 2 and first patterned wiring layer 11 of stiffener 1.

FIG. 3F is a cross-sectional view of the structure with first conductive traces 34 formed on first dielectric layer 31 by depositing first plated layer 35′ on support plate 35 and into first via openings 33 and then patterning support plate 35 and first plated layer 35′ thereon. First conductive traces 34 extend from first dielectric layer 31 in the downward direction, extend laterally on first dielectric layer 31 and extend into first via openings 33 in the upward direction to form first conductive via 33′ in direct contact with heat sink 2 and first patterned wiring layer 11. Also, first plated layer 35′ is further deposited on metal layer 12, heat sink 2, and interlayer dielectric 36 in the upward direction.

FIG. 3G is a cross-sectional view of the structure with second dielectric layer 231 disposed on first conductive traces 34 in the downward direction. The second dielectric layer 231 includes second via openings 233 to expose selected portions of first conductive traces 34.

Referring now to FIG. 3H, second conductive traces 234 are formed on second dielectric layer 231 by depositing second plated layer 235′ on second dielectric layer 231 and into second via openings 233 and then patterning second plated layer 235′. Second conductive traces 234 extend from second dielectric layer 231 in the downward direction, extend laterally on second dielectric layer 231 and extend into second via openings 233 in the upward direction to form second conductive vias 233′ in direct contact with first conductive traces 34.

Second conductive traces 234 can be deposited as a conductive layer by numerous techniques including electrolytic plating, electroless plating, sputtering, and their combinations and then patterned by numerous techniques including wet etching, electro-chemical etching, laser-assist etching, and their combinations with an etch mask (not shown) thereon that defines second conductive traces 234. Preferably, first conductive traces 34 and second conductive traces 234 are the same material with the same thickness.

Meanwhile, second plated layer 235′ is also deposited on first plated layer 35′ in the upward direction, and second patterned wiring layer 37 is formed by patterning second plated layer 235′, first plated layer 35′, and metal layer 12 of stiffener 1.

Accordingly, as shown in FIG. 3H, wiring board 103 is accomplished and includes heat sink 2, stopper 17, stiffener 1 and build-up circuitry 301. In this illustration, build-up circuitry 301 includes first dielectric layer 31, first conductive traces 34, second dielectric layer 231 and second conductive traces 234. Heat sink 2 can be affixed and mechanically connected to build-up circuitry 301 using adhesive 4 which can contact heat sink 2 and is sandwiched between heat sink 2 and build-up circuitry 301. Stiffener 1 is mechanically connected to first dielectric layer 31 via interlayer dielectric 36. The thermal conduction pathway of the wiring board 103 is provided by heat sink 2, first conductive vias 33′ that directly contact heat sink 2, and second conductive vias 233′.

FIG. 3I is a cross-sectional view of a thermally enhanced semiconductor assembly 104 in which semiconductor devices 73, 74 are electrically connected to build-up circuitry 301 via solder bumps 83′ on selected portions of second conductive traces 234. In this illustration, solder mask material 61 is disposed over build-up circuitry 301 and second patterned wiring layer 37, and includes solder mask openings that are aligned with heat sink 2, selected portions of second conductive traces 234, and selected portions of second patterned wiring layer 37. Semiconductor devices 73, 74 can be electrically connected to stiffener 1 through solder bumps 83′ and build-up circuitry 301. The thermal conduction pathway of the semiconductor assembly 104 is provided by heat sink 2 and first and second conductive vias 33′, 233′ formed in build-up circuitry 301.

### Embodiment 3

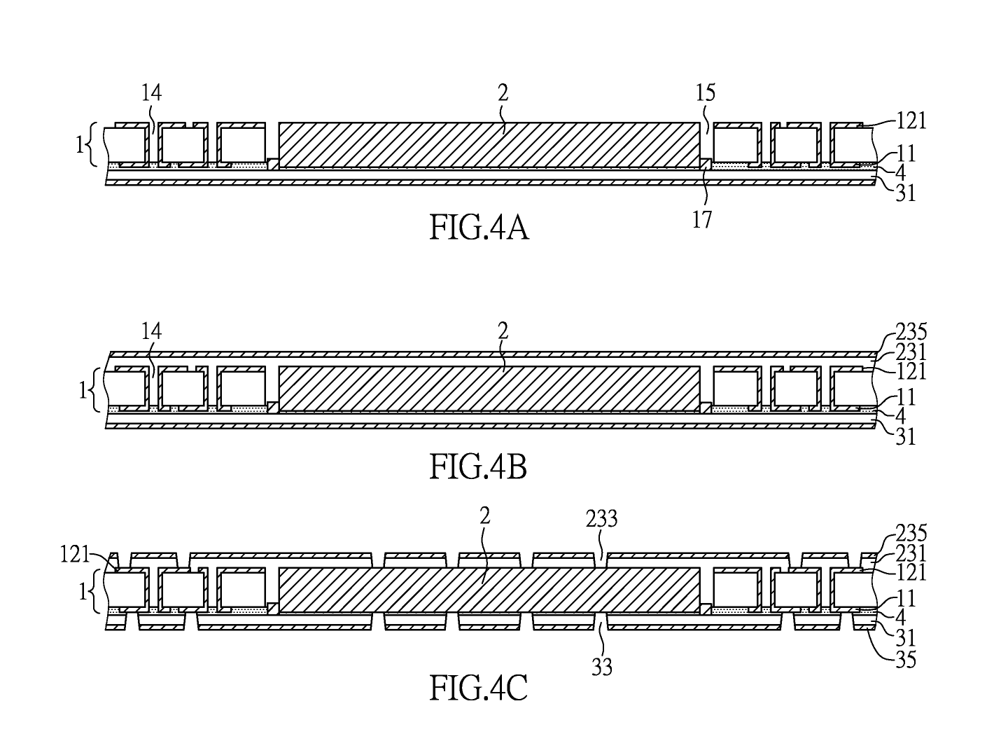

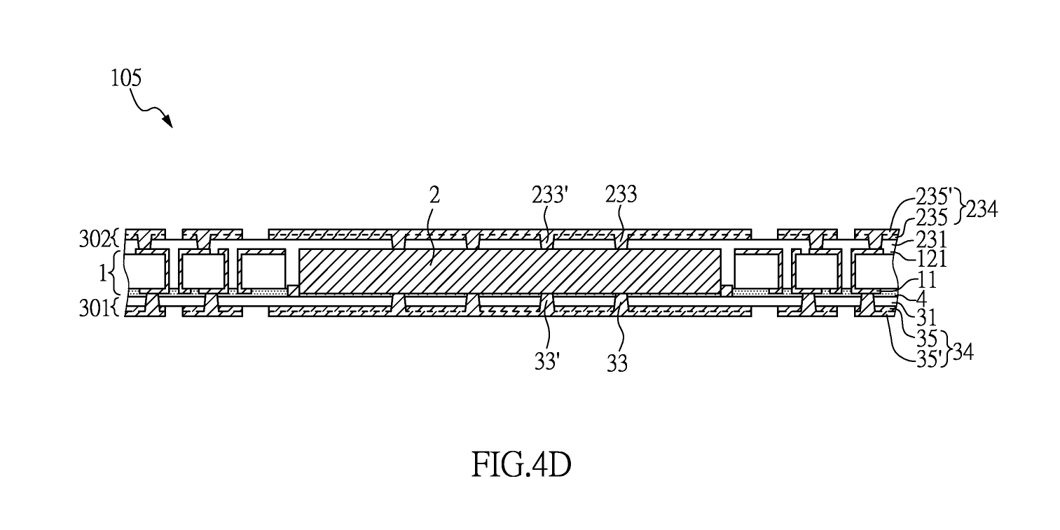

FIGS. 4A-4D are cross-sectional views showing a method of making yet another wiring board that includes an heat sink, a stopper, a stiffener and dual build-up circuitries in accordance with yet another embodiment of the present invention.

For purposes of brevity, any description in Embodiments 1 and 2 is incorporated herein insofar as the same is applicable, and the same description need not be repeated.

After the structure with heat sink 2 mounted on first dielectric layer 31 using adhesive 4 and stoppers 17 served as a placement guide referring to FIGS. 3A and 3B, stopper 17 and heat sink 2 are aligned with and extend into aperture 15 of stiffener 1, and stiffener 1 is mounted on first dielectric layer 31 using adhesive 4. As shown in FIG. 4A, heat sink 2 and aperture 15 of stiffener 1 are spaced from one another by stopper 17. Stopper 17 is close proximity to and laterally aligned with four inner walls of aperture 15 and adhesive 4 under stiffener 1 is lower than stopper 17, and thus any undesirable movement of stiffener 1 also can be avoided before adhesive 4 is fully cured. In this embodiment, stiffener 1 is a double-side wiring laminate that includes first patterned wiring layer 11, second patterned wiring layer 121, and plated through holes 14 in an electrical connection path between first patterned wiring layer 11 and second patterned wiring layer 121.

FIG. 4B is a cross-sectional view of the structure showing second dielectric layer 231 and second metal layer 235 laminated on stiffener 1 and heat sink 2 in the upward direction. Second dielectric layer 231 is sandwiched between second metal layer 235 and stiffener 1/heat sink 2. Under pressure and heat, second dielectric layer 231 is forced into a gap between stiffener 1 and heat sink 2 and remaining space of plated through holes 14 by applying downward pressure to second metal layer 235. After second dielectric layer 231 and second metal layer 235 are laminated with stiffener 1 and heat sink 2, second dielectric layer 231 is solidified.

FIG. 4C is a cross-sectional view of the structure provided with first via openings 33 and second via openings 233. First via openings 33 extend through support plate 35, first dielectric layer 31 and adhesive 4 to expose selected portions of heat sink 2 and first patterned wiring layer 11. Second via openings 233 extend through second metal plate 235 and second dielectric layer 231 to expose selected portions of heat sink 2 and second patterned wiring layer 121 of stiffener 1, respectively.

Referring now to FIG. 4D, first conductive traces 34 are formed on first dielectric layer 31 by depositing first plated layer 35′ on support plate 35 and into first via openings 33 and then patterning support plate 35 and first plated layer 35′ thereon. Meanwhile, second conductive traces 234 are formed on second dielectric layer 231 by depositing second plated layer 235′ on second metal layer 235 and then patterning second metal layer 235 and second plated layer 235′ thereon. Accordingly, first build-up circuitry 301 and second build-up circuitry 302 are accomplished. First build-up circuitry 301 includes first dielectric layer 31 and first conductive traces 34, while second build-up circuitry 302 includes second dielectric layer 231 and second conductive traces 234. First conductive traces 34 extend from first dielectric layer 31 in the downward direction, extend laterally on first dielectric layer 31 and extend into first via openings 33 in the upward direction to make electrical contact with first patented wiring layer 11 of stiffener 1. Second conductive traces 234 extend from second dielectric layer 231 in the upward direction, extend laterally on second dielectric layer 231 and extend into second via openings 233 in the downward direction to make electrical contact with second patterned wiring layer 121 of stiffener 1. Meanwhile, the thermal conduction pathway of the wiring board 105 is provided by heat sink 2 and first conductive vias 33′ formed in first build-up circuitry 301 and second conductive vias 233′ formed in second build-up circuitry 302 that both contact heat sink 2 directly. In this embodiment, heat sink 2 and stiffener 1 are affixed and mechanically connected to first build-up circuitry 301 using adhesive 4 which contacts heat sink 2 and stiffener 1 and is sandwiched between heat sink 2 and first build-up circuitry 301 and between stiffener 1 and first build-up circuitry 301.

The thermally enhanced wiring boards and semiconductor assemblies described above are merely exemplary. Numerous other embodiments are contemplated. In addition, the embodiments described above can be mixed-and-matched with one another and with other embodiments depending on design and reliability considerations. For instance, the stiffener can include ceramic material or epoxy-based laminate, and can have embedded single-level conductive traces or multi-level conductive traces. The stiffener can include multiple apertures to accommodate additional heat sinks and the build-up circuitry can include additional thermal vias to accommodate additional heat sinks.

As shown in the above embodiments, a semiconductor device can share or not share the heat sink with other semiconductor devices. For instance, a single semiconductor device can be mounted on the heat sink. Alternatively, numerous semiconductor devices can be mounted on the heat sink. For instance, four small chips in a 2×2 array can be attached to the heat sink and the stiffener can include additional contact pads to receive and route additional chip pads. This may be more cost effective than providing a heat sink for each chip. Likewise, an aperture of the stiffener can include multiple sets of stoppers to accommodate multiple additional heat sinks therein and the build-up circuitry can include additional thermal vias to accommodate additional heat sinks.

The semiconductor device can be a packaged or unpackaged chip. Furthermore, the semiconductor device can be a bare chip, or a wafer level packaged die, etc. A semiconductor device can be mechanically and electrically connected to the build-up circuitry using a wide variety of connection media including gold or solder bumps. Alternatively, a semiconductor device can be mechanically and thermally connected to the heat sink and electrically connected to the stiffener using bonding wires. The stopper can be customized for the heat sink. For instance, the stopper can have a pattern that defines a square or rectangular area with the same or similar topography as the heat sink.

The term “adjacent” refers to elements that are integral (single-piece) or in contact (not spaced or separated from) with one another. For instance, the first conductive trace is adjacent to the first patterned wiring layer but not the second patterned wiring layer.

The term “overlap” refers to above and extending within a periphery of an underlying element. Overlap includes extending inside and outside the periphery or residing within the periphery. For instance, in the position that the first patterned layer of the stiffener faces the upward direction, the first build-up circuitry overlaps the stiffener since an imaginary vertical line intersects the first build-up circuitry and the stiffener, regardless of whether another element such as the adhesive is between the first build-up circuitry and the stiffener and is intersected by the line, and regardless of whether another imaginary vertical line intersects the first build-up circuitry but not the stiffener (within the aperture of the stiffener). Likewise, the first build-up circuitry overlaps the heat sink and the heat sink is overlapped by the first build-up circuitry. Moreover, overlap is synonymous with over and overlapped by is synonymous with under or beneath.

The term “contact” refers to direct contact. For instance, the first conductive trace contacts the first patterned wiring layer but not the second patterned wiring layer.

The term “cover” refers to incomplete and complete coverage in a vertical and/or lateral direction. For instance, in the position that the first patterned wiring layer of the interposer faces the upward direction, the first build-up circuitry covers the heat sink in the upward direction regardless of whether another element such as the adhesive is between the heat sink and the first build-up circuitry, and the second build-up circuitry cover the heat sink in the downward direction.

The term “layer” refers to patterned and un-patterned layers. For instance, the metal layer disposed on the dielectric layer can be an un-patterned blanket sheet before photolithography and wet etching. Furthermore, a layer can include stacked layers.

The terms “opening”, “aperture”, “through hole” and “through via” refer to a through hole and are synonymous. For instance, in the position that the first patterned wiring layer of the stiffener faces the upward direction, the heat sink is exposed by the stiffener in the upward direction when it is inserted into the aperture in the stiffener.

The term “inserted” refers to relative motion between elements. For instance, the heat sink is inserted into the aperture regardless of whether the stiffener is stationary and the heat sink moves towards the stiffener, the heat sink is stationary and the stiffener moves towards the heat sink or the heat sink and the stiffener both approach the other. Furthermore, the heat sink is inserted (or extends) into the aperture regardless of whether it goes through (enters and exits) or does not go through (enters without exiting) the aperture.

The phrase “aligned with” refers to relative position between elements regardless of whether elements are spaced from or adjacent to one another or one element is inserted into and extends into the other element. For instance, the stopper is laterally aligned with the heat sink since an imaginary horizontal line intersects the stopper and the heat sink, regardless of whether another element is between the stopper and the heat sink and is intersected by the line, and regardless of whether another imaginary horizontal line intersects the heat sink but not the stopper or intersects the stopper but not the heat sink. Likewise, the first via opening is aligned with the first surface of the heat sink, and the heat sink is aligned with the aperture.

The phrase “in close proximity to” refers to a gap between elements not being wider than the maximum acceptable limit. As known in the art, when the gap between the heat sink and the stopper or between the heat sink and the aperture of the stiffener is not narrow enough, the location error of the heat sink due to the lateral displacement of the heat sink within the gap may exceed the maximum acceptable error limit. In some cases, once the location error of the heat sink goes beyond the maximum limit, it is impossible to align the predetermined portion of the heat sink with a laser beam, resulting in the thermal connection failure between the heat sink and the build-up circuitry. According to the dimension of the predetermined portion of the heat sink, those skilled in the art can ascertain the maximum acceptable limit for a gap between the heat sink and the stopper or the aperture of the stiffener through trial and error to ensure the thermal vias being aligned with the predetermined portion of the heat sink. Thereby, the descriptions “the stopper is in close proximity to the peripheral edges of the heat sink” and “the aperture of the stiffener is in close proximity to the peripheral edges of the heat sink” mean that the gap between the peripheral edges of the heat sink and the stopper or the aperture of the stiffener is narrow enough to prevent the location error of the heat sink from exceeding the maximum acceptable error limit.

The phrase “mounted on” includes contact and non-contact with a single or multiple support element(s). For instance, the semiconductor device is mounted on the heat sink regardless of whether it contacts the heat sink or is separated from the heat sink by an adhesive.

The phrase “electrical connection” or “electrically connects” or “electrically connected” refers to direct and indirect electrical connection. For instance, the first conductive trace provides an electrical connection between the terminal pad and the first patterned wiring layer regardless of whether the first conductive trace is adjacent to the terminal pad or electrically connected to the terminal pad by additional conductive traces of the first build-up circuitry.

The term “above” refers to upward extension and includes adjacent and non-adjacent elements as well as overlapping and non-overlapping elements. For instance, in the position that the second patterned wiring layer of the stiffener faces the upward direction, the stopper extends above, is adjacent to and protrudes from the dielectric layer.

The term “below” refers to downward extension and includes adjacent and non-adjacent elements as well as overlapping and non-overlapping elements. For instance, in the position that the second patterned wiring layer of the stiffener faces the upward direction, the build-up circuitry extends below the stiffener and the heat sink in the downward direction regardless of whether the build-up circuitry is adjacent to the stiffener and the heat sink.

The “first vertical direction” and “second vertical direction” do not depend on the orientation of the wiring board, as will be readily apparent to those skilled in the art. For instance, the first patterned wiring layer of the stiffener faces the first vertical direction and the second patterned wiring layer of the stiffener faces the second vertical direction regardless of whether the wiring board is inverted. Likewise, the stopper is “laterally” aligned with the heat sink in a lateral plane regardless of whether the wiring board is inverted, rotated or slanted. Thus, the first and second vertical directions are opposite one another and orthogonal to the lateral directions, and a lateral plane orthogonal to the first and second vertical directions intersects laterally aligned elements. Furthermore, the first vertical direction is the downward direction and the second vertical direction is the upward direction in the position that the second patterned wiring layer of the stiffener faces the upward direction, and the first vertical direction is the upward direction and the second vertical direction is the downward direction in the position that the second patterned wiring layer of the stiffener faces the downward direction.

The thermally enhanced wiring board and the semiconductor assembly using the same according to the present invention have numerous advantages. The wiring board and the semiconductor assembly are reliable, inexpensive and well-suited for high volume manufacture. The through via in the stiffener can provide flexible signal routing when interconnected with build-up circuitry. The strong rigidity of the stiffener can provide a robust mechanical support for the heat sink and the build-up circuitry. The placement location of the heat sink can be accurately confined by the aperture of the stiffener or the stopper to avoid the thermal connection failure between the heat sink and the build-up circuitry resulted from the lateral displacement of the heat sink, thereby improving the manufacturing yield greatly. The direct thermal connection between the heat sink and the build-up circuitry is advantageous for a high thermal conduction pathway. In addition, the direct electrical connection between the stiffener and the build-up circuitry is advantageous for high I/O and high performance applications due to its high routing capability. The thermally enhanced wiring board and the semiconductor assembly using the same are reliable, inexpensive and well-suited for high volume manufacture.

The manufacturing process is highly versatile and permits a wide variety of mature electrical and mechanical connection technologies to be used in a unique and improved manner. The manufacturing process can also be performed without expensive tooling. As a result, the manufacturing process significantly enhances throughput, yield, performance and cost effectiveness compared to conventional packaging techniques.

The embodiments described herein are exemplary and may simplify or omit elements or steps well-known to those skilled in the art to prevent obscuring the present invention. Likewise, the drawings may omit duplicative or unnecessary elements and reference labels to improve clarity.

Various changes and modifications to the embodiments described herein will be apparent to those skilled in the art. For instance, the materials, dimensions, shapes, sizes, steps and arrangement of steps described above are merely exemplary. Such changes, modifications and equivalents may be made without departing from the spirit and scope of the present invention as defined in the appended claims.

Although the present invention has been explained in relation to its preferred embodiment, it is to be understood that many other possible modifications and variations can be made without departing from the spirit and scope of the invention as hereinafter claimed.

What is claimed is:

1. A thermally enhanced wiring board with a built-in heat sink, comprising:
a stiffener that includes a first patterned wiring layer, a second patterned wiring layer, and an aperture, wherein the first patterned wiring layer faces a first vertical direction and the second patterned wiring layer faces a second vertical direction opposite the first vertical direction, and the first patterned wiring layer is electrically connected to the second patterned wiring layer;
the heat sink that extends into the aperture of the stiffener and includes a first surface and a parallel second surface, wherein the first surface faces the first vertical direction, the second surface faces the second vertical direction; and
a build-up circuitry that covers the heat sink and the stiffener in the first vertical direction and includes a first dielectric layer, first via openings, and a first conductive trace, wherein the first via openings in the first dielectric layer are aligned with the heat sink and the first patterned wiring layer, and the first conductive trace extends from the first dielectric layer in the first vertical direction and extends through the first via openings in the second vertical direction and directly contacts the heat sink and the first patterned wiring layer respectively.

2. The thermally enhanced wiring board with a built-in heat sink of claim 1, wherein the aperture of the stiffener is in close proximity to and be laterally aligned with peripheral edges of the heat sink in the lateral directions orthogonal to the vertical directions.

3. The thermally enhanced wiring board with a built-in heat sink of claim 1, further comprising an adhesive that contacts and is sandwiched between the heat sink and the build-up circuitry and between the stiffener and the build-up circuitry.

4. The thermally enhanced wiring board with a built-in heat sink of claim 3, further comprising a stopper that serves as a placement guide for the heat sink and is in close proximity to and laterally aligned with and laterally extends beyond peripheral edges of the heat sink in lateral directions orthogonal to the vertical directions.

5. A thermally enhanced wiring board with a built-in heat sink, comprising:
a stiffener that includes a first patterned wiring layer, a second patterned wiring layer, and an aperture, wherein the first patterned wiring layer faces a first vertical direction and the second patterned wiring layer faces a second vertical direction opposite the first vertical direction and the first patterned wiring layer is electrically connected to the second patterned wiring layer;
the heat sink that extends into the aperture of the stiffener and includes an first surface and a parallel second surface, wherein the first surface faces the first vertical direction, the second surface faces the second vertical direction;
a first build-up circuitry that covers the heat sink and the stiffener in the first vertical direction and includes a first dielectric layer, first via openings, and a first conductive trace, wherein the first via openings in the first dielectric layer are aligned with the heat sink and the first patterned wiring layer, and the first conductive trace extends from the first dielectric layer in the first vertical direction and extends through the first via openings in the second vertical direction and directly contacts the heat sink and the first patterned wiring layer respectively; and
a second build-up circuitry that covers the heat sink and the stiffener in the second vertical direction and includes a second dielectric layer, second via openings, and a second conductive trace, wherein the second via openings in the second dielectric layer are aligned with the heat sink and the second patterned wiring layer, and the second conductive trace extends from the second dielectric layer in the second vertical direction and extends through the second via openings in the first vertical direction and directly contacts the heat sink and the second patterned wiring layer respectively.

6. The thermally enhanced wiring board with a built-in heat sink of claim 5, wherein the aperture of the stiffener is in close proximity to and be laterally aligned with peripheral edges of the heat sink in the lateral directions orthogonal to the vertical directions.

7. The thermally enhanced wiring board with a built-in heat sink of claim 5, further comprising an adhesive that contacts and is sandwiched between the heat sink and the first build-up circuitry and between the stiffener and first the build-up circuitry.

8. The thermally enhanced wiring board with a built-in heat sink of claim 7, further comprising a stopper that serves as a placement guide for the heat sink and is in close proximity to and laterally aligned with and laterally extends beyond peripheral edges of the heat sink in lateral directions orthogonal to the vertical directions.
